(19) United States
(12) Patent Application Publication
(10) Pub. No.: US 2025/0085756 A1
(43) Pub. Date: Mar. 13, 2025

(54) POWER SUPPLY SYSTEM AND CONTROL METHOD FOR DATA CENTER, AND DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/827,473

(22) Filed: Sep. 6, 2024

(30) Foreign Application Priority Data
Sep. 11, 2023 (CN) 202311168672.9

(51) Int. Cl. G06F 1/26; H02J 3/00; H02J 3/38; H05K 7/20

(52) U.S. Cl. CPC G06F 1/266; H02J 3/0075; H02J 3/38; H05K 7/20709; H02J 2300/24; H02J 2300/28

(57) ABSTRACT

The present disclosure discloses a power supply system for a data center, where the data center includes a power distribution device. The power supply system includes a 220 kV/20 kV substation and a 20 kV power distribution system. The 220 kV/20 kV substation is connected to a power grid and the power distribution system, respectively, and is configured to convert a 220 kV voltage outputted by the power grid into a 20 kV voltage and output the 20 kV voltage to the power distribution system. The 20 kV power distribution system is connected to the power distribution device of the data center, and is configured to distribute the 20 kV voltage outputted by the substation to the power distribution device of the data center.

### CROSSREFERENCE TO RELATED APPLICATION

This application claims priority to Chinese Patent Application No. 202311168672.9, titled “POWER SUPPLY SYSTEM AND CONTROL METHOD FOR DATA CENTER, AND DATA CENTER” and filed to the China National Intellectual Property Administration on Sep. 11, 2023, the entire contents of which are incorporated herein by reference.

### TECHNICAL FIELD

The present disclosure relates to the field of data center technology, and more particularly, to a power supply system and a control method for a data center, and the data center.

### BACKGROUND

At present, as users' demands for data storage are increasing, scale of the data centers may expand, and large-scale data centers also have greater power supply demands.

In related technologies, a 220 kV substation is employed to supply power to the large-scale data centers, which can meet the greater power supply demands of the data centers. However, a low-voltage side of the 220 kV substation typically uses a voltage level of 10 kV. Because the voltage level of 10 kV is lower, impedance of a corresponding main transformer is higher, which causes greater power supply losses to the substation, thus having a negative effect on power supply efficiency of the substation.

It is to be noted that the above information disclosed in this Background section is only for enhancement of understanding of the background of the present disclosure and therefore it may contain information that does not form the prior art that is already known to a person of ordinary skill in the art.

### SUMMARY

To have a basic understanding of some aspects of the embodiments of the present disclosures, a brief summary is provided below. The summary neither is a general review, nor is intended to determine key/important constituent elements or describe a protection scope of these embodiments, but rather serves as a preface to the detailed description that follows.

The embodiments of the present disclosure provide a power supply system and a control method for a data center, and the data center. When the data center supplies power using a 220 kV substation, power supply losses of the substation can be reduced, to improve power supply efficiency of the substation.

In some embodiments, the data center includes a power distribution device and at least one server, where the power distribution device is configured to distribute the power supplied by the power supply system to the at least one server. The power supply system includes a substation and a power distribution system.

The 220 kV/20 kV substation is connected to a power grid and the power distribution system, respectively, and is configured to convert a 220 kV voltage outputted by the power grid into a 20 kV voltage and output the 20 kV voltage to the power distribution system.

The 20 kV power distribution system is connected to the power distribution device of the data center, and is configured to distribute the 20 kV voltage outputted by the substation to the power distribution device of the data center.

In some embodiments, the data center includes a power supply system, a controller, a power distribution device, and at least one server. The power distribution device is configured to distribute power supplied by the power supply system to the at least one server. The method is applied to the controller of the data center. The power supply system for the data center includes a substation, a power distribution system, and a voltage level detection apparatus. The 220 kV/20 kV substation is connected to a power grid and the power distribution system, respectively, and is configured to convert a 220 kV voltage outputted by the power grid into a 20 kV voltage and output the 20 kV voltage to the power distribution system. The 20 kV power distribution system is connected to the power distribution device of the data center, and is configured to distribute the 20 kV voltage outputted by the substation to the power distribution device of the data center. The voltage level detection apparatus is connected to the power distribution device of the data center, and is configured to detect a voltage level of the data center. The method includes:

obtaining the voltage level of the data center; and

controlling, based on the voltage level of the data center, the power distribution system to convert the 20 kV voltage into a voltage equivalent to the voltage level.

In some embodiments, the data center includes a power distribution device, at least one server, and the aforementioned power supply system. The power distribution device is configured to distribute the power supplied by the power supply system to the at least one server.

The power supply system and the control method for the data center, and the data center provided in the embodiments of the present disclosure can achieve following technical effects.

In the process of supplying power to the data center, compared to using a 220 kV/10 kV substation, using the 220 kV/20 kV substation improves a voltage level of a low-voltage side of the substation. In this way, when power supply capability of the 220 kV substation remains unchanged, improving the voltage level of the low-voltage side of the substation can reduce impedance of a main transformer in the substation. Thus, power supply losses of the substation are reduced, thereby improving power supply efficiency of the substation.

Both the foregoing general description and the following detailed description are exemplary and explanatory only and are not intended to limit the present disclosure.

### BRIEF DESCRIPTION OF THE DRAWINGS

Exemplary descriptions are made to one or more embodiments with reference to pictures in the corresponding drawings, and these exemplary descriptions and drawings do not constitute limitations on the embodiments, and elements with the same reference numerals in the drawings are denoted as similar elements. Unless otherwise stated, the drawings do not constitute a scale limitation, in which:

FIG. 1 is a schematic diagram of a data center according to an embodiment of the present disclosure;

FIG. 2 is a schematic diagram of a power supply system for a data center according to an embodiment of the present disclosure;

FIG. 3 is a schematic diagram of a substation and a power distribution system in a power supply system for a data center according to an embodiment of the present disclosure;

FIG. 4 is a schematic diagram of another power supply system for a data center according to an embodiment of the present disclosure; and

FIG. 5 is a flowchart of a power supply control method for a data center according to an embodiment of the present disclosure.

Reference numerals in the attached drawings:

data center 100; power supply system 11; power distribution device 12; server 13; substation 21; power distribution system 22; voltage level detection apparatus 23; controller 24; photovoltaic power supply apparatus 25; wind power supply apparatus 26; heat dissipating apparatus 27; input terminal 211; main transformer 212; output terminal 213; incoming cabinet 221; busbar 222; outgoing line 223; and step-down transformer 224.

### DETAILED DESCRIPTION

To gain a more detailed understanding of the characteristics and technical contents of the embodiments of the present disclosure, a detailed description is made to implementation of the embodiments of the present disclosure in conjunction with the accompanying drawings, which serve for reference only and are not intended to limit the embodiments of the present disclosure. In the following technical description, for convenience of explanation, multiple details are provided to provide a comprehensive understanding of the embodiments disclosed. However, one or more embodiments can still be implemented without these details. In other cases, to simplify the drawings, familiar structures and apparatuses can be simplified for display.

In the specification, the claims and the foregoing accompanying drawings of the embodiments of the present disclosure, a term such as “first” or “second” is intended to separate between similar objects but is not intended to describe a specific sequence or precedence order. It is to be understood that data used like this may be interchangeable where appropriate, such that the embodiments of the present disclosure described herein may be implemented. Furthermore, the terms “comprise” and “have” as well as variants thereof are intended to cover non-exclusive inclusion.

Unless otherwise stated, the term “a plurality of” refers to two or more.

In the embodiments of the present disclosure, the character “/”' indicates that an “or” relationship is between association objects. For example, A/B represents A or B.

The term “and/or” used for describing an association relationship between the association objects represents presence of three relationships. For example, A and/or B may represent presence of A only, presence of both A and B, and presence of B only.

The term “correspondence” may refer to an association relationship or a binding relationship, and that A corresponds to B refers to an association relationship or a binding relationship between A and B.

At present, as users' demands for data storage are increasing, scale of the data centers may expand, and large-scale data centers also have greater power supply demands.

In related technologies, a 220 kV substation is employed to supply power to the large-scale data centers, which can meet the greater power supply demands of the data centers. However, a low-voltage side of the 220 kV substation typically uses a voltage level of 10 kV. Because the voltage level of 10 kV is lower, impedance of a corresponding main transformer is higher, which causes greater power supply losses to the substation, thus having a negative effect on power supply efficiency of the substation.

In view of this, the embodiments of the present disclosure provide a power supply system and control method for a data center. In the process of supplying power to the data center, compared to using a 220 kV/10 kV substation, using the 220 kV/20 kV substation improves a voltage level of a low-voltage side of the substation. Thus, power supply losses of the substation are reduced, thereby improving power supply efficiency of the substation.

To make the objectives, technical solutions, and advantages of the embodiments of the present disclosure clearer, the technical solutions in the embodiments of the present disclosure will be described clearly and completely below with reference to the accompanying drawings in the embodiments of the present disclosure. Apparently, the described embodiments are some but not all of the embodiments of the present disclosure.

All other embodiments obtained by a person of ordinary skill in the art based on the embodiments of the present disclosure without creative efforts shall fall within the protection scope of the present disclosure. The following embodiments and features thereof may be combined with each other on a non-conflict basis.

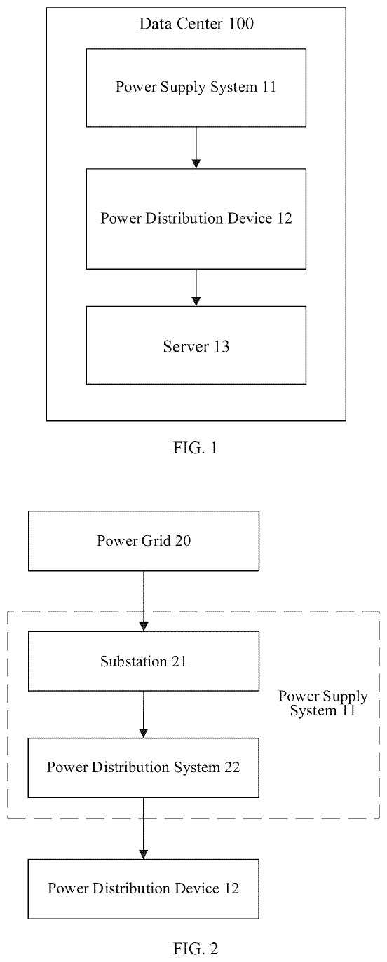

With reference to FIG. 1, a data center 100 provided in the embodiments of the present disclosure may include a power supply system 11, a power distribution device 12, and at least one server 13. The power distribution device 12 is configured to distribute power supplied by the power supply system 11 to the at least one server 13.

With reference to FIG. 1 and FIG. 2, the power supply system 11 provided in the embodiments of the present disclosure may include a substation 21 and a power distribution system 22.

The 220 kV/20 kV substation 21 is connected to a power grid 20 and the power distribution system 22, respectively, and is configured to convert a 220 kV voltage outputted by the power grid 20 into a 20 kV voltage and output the 20 kV voltage to the power distribution system 22.

The 20 kV power distribution system 22 is connected to the power distribution device 12 of the data center 100, and is configured to distribute the 20 kV voltage outputted by the substation to the power distribution device 12 of the data center 100.

By using the power supply system for the data center provided in the embodiments of the present disclosure, in the process of supplying power to the data center, compared to using the 220 kV/10 kV substation, using the 220 kV/20 kV substation can improve the voltage level of the low-voltage side of the substation. In this way, when power supply capability of the 220 kV substation remains unchanged, improving the voltage level of the low-voltage side of the substation can reduce impedance of a main transformer in the substation. Thus, the power supply losses of the substation are reduced, thereby improving the power supply efficiency of the substation.

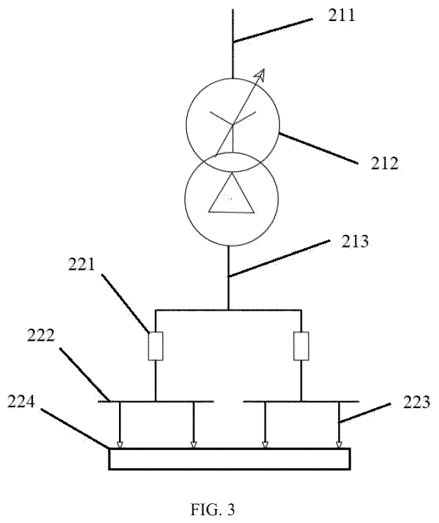

Alternatively, with reference to FIG. 3, the substation 21 includes an input terminal 211, a main transformer 212, and an output terminal 213 connected in sequence. The input terminal 211 is connected to the power grid 20 and can receive the 220 kV voltage from the power grid 20. The main transformer 212 can reduce the voltage from 220 kV to 20 kV. The output terminal 213 is connected to the power distribution system 22 and can output the 20 kV voltage to the power distribution system 22. In this embodiment, the low-voltage side of the main transformer 212 uses a dual-branch wiring method, and the main transformer 212 does not need to use a split winding form. As a result, reactive power configuration of the main transformer 212 is reduced.

Alternatively, with reference to FIG. 3, the power distribution system 22 includes an incoming cabinet 221, a busbar 222, an outgoing line 223, and a step-down transformer 224. The incoming cabinet 221 is connected to the substation 21 and can receive the 20 kV voltage outputted by the substation 21. The busbar 222 is connected to the incoming cabinet 221 and can receive the 20 kV voltage distributed by the incoming cabinet 221. The outgoing line 223 is connected to the busbar 222 and can transmit the 20 kV voltage from the busbar 222 to the step-down transformer 224. The step-down transformer 224 is connected to the outgoing line 223 and the power distribution device 12 of the data center 100, respectively, and can convert the 20 kV voltage into a voltage equivalent to a voltage level of the data center 100. In this embodiment, the main transformer 212 only corresponds to two segments of busbars 222, and only requires two incoming cabinets 221. In this way, a structure of the power supply system is simpler, and number of the corresponding outgoing lines 223 is also smaller. Thus, use and laying costs of the outgoing lines 223 are reduced.

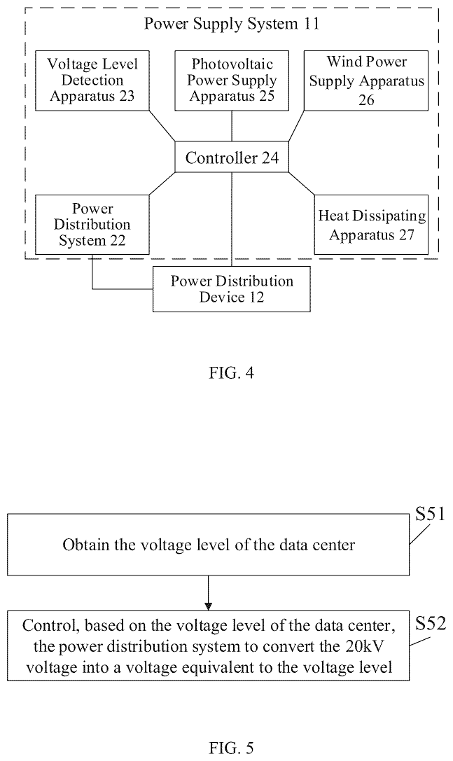

Alternatively, with reference to FIG. 2, FIG. 3, and FIG. 4, the power supply system 11 provided in the embodiments of the present disclosure also includes a voltage level detection apparatus 23 and a controller 24.

The voltage level detection apparatus 23 is connected to the power distribution device 12 of the data center 100, and can detect the voltage level of the data center by means of the power distribution device 12.

The controller 24 is connected to the voltage level detection apparatus 23 and the power distribution system 22, respectively. The controller 24 can control, based on the voltage level of the data center 100, the power distribution system 22 to convert the 20 kV voltage into a voltage equivalent to the voltage level. For example, the voltage level of the data center 100 is 10 kV, and the power distribution system 22 can reduce the voltage from 20 kV to 10 kV by means of the step-down transformer 224, such that the voltage supplied by the power supply system 11 can be normally used by the data center 100. In this way, matching the voltage supplied by the power supply system 11 with the voltage level of the data center can improve adaptability of the power supply system 11, such that an application scope of the power supply system 11 is more extensive. In addition, by using the power supply system 11 in this embodiment, it is not required to make hardware adjustment to the power distribution device 12 of the data center 100, thereby saving costs.

Alternatively, with reference to FIG. 2 and FIG. 4, the power supply system 11 provided in the embodiments of the present disclosure also includes a photovoltaic power supply apparatus 25 and a wind power supply apparatus 26. The controller 24 can obtain the power supply demands of the data center 100, and can control to start up the photovoltaic power supply apparatus 25 and/or the wind power supply apparatus 26 when electric energy outputted by the power supply system 11 cannot meet the power supply demands. Thus, it is beneficial to better supply power to the data center 100, which can reduce occurrence of anomalies due to insufficient power supply.

Alternatively, with reference to FIG. 2 and FIG. 4, the power supply system 11 provided in the embodiments of the present disclosure also includes a heat dissipating apparatus 27. The controller 24 can determine whether temperature of the power supply system 11 is above a temperature threshold, and control to start up the heat dissipating apparatus 27 when the temperature of the power supply system 11 is above the temperature threshold. Thus, heat can be dissipated timely from the power supply system 11, to reduce the occurrence of high temperature inside the power supply system 11.

Based on the above data center, the embodiments of the present disclosure also provide a power supply control method for the data center, and the method can be applied to the controller 24 of the data center 100. With reference to FIG. 5, the method includes following steps.

In Step S51, the voltage level of the data center 100 is obtained.

In Step S52, based on the voltage level of the data center 100, the power distribution system 22 is controlled to convert the 20 kV voltage into the voltage equivalent to the voltage level.

By adopting the power supply control method for the data center provided in the embodiments of the present disclosure, the voltage supplied by the power supply system 11 can be matched with the voltage level of the data center to improve the adaptability of the power supply system 11, such that the application scope of the power supply system 11 is more extensive. In addition, by using the power supply system 11 in this embodiment, it is not required to make hardware adjustment to the power distribution device 12 of the data center 100, thereby saving the costs.

Alternatively, the above power supply control method also includes: controlling to start up the photovoltaic power supply apparatus 25 and/or the wind power supply apparatus 26 when electric energy outputted by the power supply system 11 cannot meet the power supply demands. Thus, it is beneficial to better supply power to the data center 100, which can reduce the occurrence of the anomalies due to insufficient power supply.

Alternatively, the above power supply control method also includes: determining whether the temperature of the power supply system is above the temperature threshold. The heat dissipating apparatus 27 is controlled to start up when the temperature of the power supply system 11 is above the temperature threshold. Thus, the heat can be dissipated timely from the power supply system 11, to reduce the occurrence of high temperature inside the power supply system 11.

The technical solutions of the embodiments of the present disclosure may be embodied in the form of software products, which may be stored in a storage medium, including one or more instructions to cause a computer device (a personal computer, a server or a network device and so on) to execute all or part of steps of the method as recited in the embodiments of the present disclosure. The foregoing storage medium may be various medium that can store program codes, such as a Universal Serial Bus (USB) flash disk, a removable hard disk, a read-only memory (ROM), a random-access memory (RAM), a magnetic disk, or an optical disc. The storage medium may also be transient storage medium.

The above descriptions and the accompanying drawings fully illustrate the embodiments of the present disclosure to enable those skilled in the art to practice them. Other embodiments may include structural, logical, electrical, process, and other changes. The embodiments only represent possible changes. Unless explicitly specified, independent components and functions are optional, and an operation sequence may change. Portions and features of some embodiments can be included in, or substituted for, those of other embodiments. Moreover, the terms used in the present disclosure are only for describing the embodiments and are not intended to limit the claims. As used in the descriptions of the embodiments and the claims, singular forms “a”, “an”, and “the” are intended to also include plural forms, unless the context clearly indicates otherwise. Similarly, as used in the present disclosure, the term “and/or” refers to any and all possible combinations that include one or more associated lists. In addition, the term “comprise” and its variants such as “comprises” and/or “comprising” used in the present disclosure refer to the presence of the stated features, integers, steps, operations, elements, and/or components, but not exclusive of the presence or addition of one or more other features, integers, steps, operations, elements, components, and/or groups of thereof. In the case of no more restrictions, elements restricted by a sentence “include a . . . ” do not exclude the fact that additional identical elements may exist in a process, a method or a device of these elements. Herein, each of the embodiments is focused on difference from other embodiments, and references may be made among these embodiments with respect to the same or similar portions among these embodiments. For the methods, products, etc. disclosed in the embodiments, if they correspond to the method section disclosed in the embodiments, reference may be made to the description of the method section for relevant parts.

Those skilled in the art may realize that units and algorithm steps in various examples as described in embodiments disclosed herein can be implemented by electronic hardware or a combination of computer software and electronic hardware. Whether these functions are executed in a hardware mode or a software mode depends on specific applications and design constraints on the technical solutions. Those skilled in the art may use different methods to implement the functions set forth in each of the specific applications. However, the implementation shall be not believed beyond the scope of the embodiments of the present disclosure. Those skilled in the art may clearly understand that for a convenient and concise description, a concrete work process of systems, apparatuses and units described above may refer to a corresponding process of the foregoing method embodiments, which is not repeated anymore herein.

In the embodiments disclosed herein, the disclosed methods and products (including but not limited to apparatuses, devices, etc.) may be implemented through other means. For example, the apparatus embodiments described above are merely exemplary. For example, a unit partition is merely a logic functional partition. In actual implementation, additional manners of partitioning may be available. For example, a plurality of units or components may be combined or integrated into another system, or some features may be ignored or not executed. In addition, intercoupling or direct coupling or communications connection displayed or discussed may be indirect coupling or communications connection, electrical or mechanical or in other forms, by means of some interfaces, apparatuses or units. The unit serving as a detached component may be or not be physically detached, the component serving as a unit display may be or not be a physical unit, i.e., either located at one place or distributed on a plurality of network elements. Units may be selected in part or in whole according to actual needs to achieve this embodiment. In addition, various functional units in the embodiments of the present disclosure may be integrated into one processing unit, or various units may be separately or physically existent, or two or more units may be integrated into one unit.

The flowcharts and block diagrams in the drawings illustrate architectures, functions and operations that may be implemented according to the system, the method and the computer program product of the embodiments of the present disclosure. In this regard, each block in the flowcharts and block diagrams may represent a module, a program segment, or a code portion. The module, the program segment, or the code portion includes one or more executable instructions for implementing the specified logical function. In some alternative implementations, the functions denoted by the blocks may occur in a sequence different from the sequences shown in the drawings. For example, in practice, two blocks in succession may be executed, depending on the involved functionalities, substantially in parallel, or in a reverse sequence. In the description corresponding to the flowcharts and block diagrams in the attached drawings, the operations or steps corresponding to different blocks may also occur in a different order than disclosed in the description, and sometimes there is no specific order between different operations or steps. For example, in practice, two operations or steps in succession may be executed, depending on the involved functionalities, substantially in parallel, or in a reverse sequence. Each block in the block diagrams and/or the flowcharts and/or a combination of the blocks in the block diagrams and/or the flowcharts may be implemented by a dedicated hardware-based system executing specific functions or operations, or by a combination of a dedicated hardware and computer instructions.

What is claimed is:

1. A power supply system for a data center, the data center comprising a power distribution device and at least one server, the power distribution device being configured to distribute power supplied by the power supply system to the at least one server, and the power supply system comprising a substation and a power distribution system; wherein
the 220 kV/20 kV substation is connected to a power grid and the power distribution system, respectively, and is configured to convert a 220 kV voltage outputted by the power grid into a 20 kV voltage and output the 20 kV voltage to the power distribution system; and
the 20 kV power distribution system is connected to the power distribution device of the data center, and is configured to distribute the 20 kV voltage outputted by the substation to the power distribution device of the data center.

2. The power supply system according to claim 1, wherein the substation comprises an input terminal, a main transformer, and an output terminal connected in sequence;
the input terminal is connected to the power grid, and is configured to receive the 220 kV voltage from the power grid;
the main transformer is configured to reduce the 220 kV voltage to the 20 kV voltage; and
the output terminal is connected to the power distribution system, and is configured to output the 20 kV voltage to the power distribution system.

3. The power supply system according to claim 1 further comprising:
an incoming cabinet connected to the substation, the incoming cabinet being configured to receive the 20 kV voltage outputted by the substation;
a busbar connected to the incoming cabinet, the busbar being configured to receive the 20 kV voltage distributed by the incoming cabinet;
an outgoing line connected to the busbar, the outgoing line being configured to transmit the 20 kV voltage from the busbar to a step-down transformer; and
the step-down transformer connected to the outgoing line and the power distribution device of the data center, respectively, the step-down transformer being configured to convert the 20 kV voltage into a voltage equivalent to a voltage level of the data center.

4. The power supply system according to claim 3, wherein the power supply system further comprises:
a voltage level detection apparatus connected to the power distribution device of the data center, the voltage level detection apparatus being configured to detect the voltage level of the data center; and
a controller connected to the voltage level detection apparatus and the power distribution system, respectively, the controller being configured to control, based on the voltage level of the data center, the power distribution system to convert the 20 kV voltage into the voltage equivalent to the voltage level.

5. The power supply system according to claim 4 further comprising a photovoltaic power supply apparatus and a wind power supply apparatus, wherein the controller is further configured to obtain a power supply demand of the data center, and control to start up the photovoltaic power supply apparatus and/or the wind power supply apparatus when electric energy outputted by the power supply system cannot meet the power supply demand.

6. The power supply system according to claim 3, wherein the power supply system further comprises:
a heat dissipating apparatus configured to dissipate heat from the power supply system when temperature of the power supply system is above a temperature threshold.

7. A power supply control method for a data center, the data center comprising a power supply system, a controller, a power distribution device, and at least one server, the power distribution device being configured to distribute power supplied by the power supply system to the at least one server; wherein the method is applied to the controller of the data center; the power supply system for the data center comprises a substation, a power distribution system, and a voltage level detection apparatus; the 220 kV/20 kV substation is connected to a power grid and the power distribution system, respectively, and is configured to convert a 220 kV voltage outputted by the power grid into a 20 kV voltage and output the 20 kV voltage to the power distribution system; the 20 kV power distribution system is connected to the power distribution device of the data center, and is configured to distribute the 20 kV voltage outputted by the substation to the power distribution device of the data center; the voltage level detection apparatus is connected to the power distribution device of the data center, and is configured to detect a voltage level of the data center; and the power supply control method comprises:
obtaining the voltage level of the data center; and
controlling, based on the voltage level of the data center, the power distribution system to convert the 20 kV voltage into a voltage equivalent to the voltage level.

8. The power supply control method according to claim 7, wherein the power supply system further comprises a photovoltaic power supply apparatus and a wind power supply apparatus; and the power supply control method further comprises:
controlling to start up the photovoltaic power supply apparatus and/or the wind power supply apparatus when electric energy outputted by the power supply system cannot meet a power supply demand.

9. The power supply control method according to claim 8, wherein the power supply system further comprises a heat dissipating apparatus; and the power supply control method further comprises:
determining whether temperature of the power supply system is above a temperature threshold; and
controlling to start up the heat dissipating apparatus when the temperature of the power supply system is above the temperature threshold.

10. A data center comprising a power distribution device, at least one server, and the power supply system as claimed in claim 6; wherein the power distribution device is configured to distribute power supplied by the power supply system to the at least one server.
